(19) United States
(12) Patent Application Publication
(10) Pub. No.: US 2019/0115216 A1
(43) Pub. Date: Apr. 18, 2019

(54) NANO-COMPOUND FIELD-EFFECT TRANSISTOR AND MANUFACTURING METHOD THEREFOR

(71) Applicant: NDD, INC., Gumi-si, Gyeongsangbuk-do (KR)

(72) Inventors: Sae Young AHN, Seoul (KR); Hyun Hwa KWON, Gumi-si, Gyeongsangbuk-do (KR)

(73) Assignee: NDD, INC., Gumi-si, Gyeongsangbuk-do (KR)

(21) Appl. No.: 16/088,741

(22) PCT Filed: Dec. 15, 2016
(86) PCT No.: PCT/KR2016/014681

§ 371 Date: Sep. 26, 2018

(30) Foreign Application Priority Data
Nov. 28, 2016 (KR) 10-2016-0158904

(51) Int. Cl. H01L 21/268; H01L 29/10; H01L 29/772; B23K 26/00

(52) U.S. Cl. CPC H01L 21/268; B23K 26/0006; H01L 29/772; H01L 29/10

(57) ABSTRACT

The purpose of the present invention is to provide a nano-compound field-effect transistor formed by fusing, on a gate, a channel part having a nano-compound coated on an insulating film, and a manufacturing method therefor. To this end, a nanocompound field-effect transistor, according to the present invention, has: a gate formed on a substrate; a channel part bonded on the gate so as to be overlapped on the gate; a source formed on one end of the channel part; and a drain formed so as to face the source at the other end of the channel part by having the gate interposed therebetween, wherein the channel part comprises an insulating film and a nano-compound coated on the insulating film, the insulating film is bonded to the gate and the substrate, and the source and the drain are overlapped on the nano-compound.

### TECHNICAL FIELD

The present invention relates to a field-effect transistor and a manufacturing method therefor, and more particularly, to a nano-compound field-effect transistor which can be used as a sensor and a manufacturing method therefor.

This application claims priority based on the Korea Patent Application No. 10-2016-0158904, filed on Nov. 28, 2016, the entire contents of which are incorporated herein by reference.

### BACKGROUND ART

Miniaturization of field-effect transistors is reaching more and more limitations.

As a way to overcome the limitations on the miniaturization of the field-effect transistors, a carbon nanotube (CNT), graphene, MoS₂, or the like has been proposed, and an integrated circuit (IC) using the same has also been developed.

In particular, since a semiconductor chip including the field-effect transistor using the carbon nanotube (hereinafter, simply referred to as a CNT-FET) may be used as a biosensor, studying on the CNT-FET is being conducted actively.

For example, the semiconductor chip including the CNT-FET can measure, in unit of picograms, an antigen to be detected, and in particular, measurement can be performed in real-time.

However, according to the related art, it is difficult for the carbon nanotube (CNT) to be uniformly applied onto an insulating film, and therefore, it is difficult to uniformly form a channel.

Therefore, the stability of the channel formed with the carbon nanotube (CNT) according to the related art is very low, and it is thus difficult to commercialize the biosensor that uses the CNT-FET.

### Detailed Description of the Invention Technical Problem

The object of the present invention proposed to overcome the above limitations is to provide a nano-compound field-effect transistor formed by bonding, on a gate, a channel part in which a nano-compound is applied on an insulating film, and a manufacturing method therefor.

### Technical Solution

To achieve above technical end, according to the present invention, a nano-compound field-effect transistor includes: a gate on a substrate; a channel part bonded on the gate so as to overlap with the gate; a source at one end of the channel part; and a drain facing the source at the other end of the channel part with the gate disposed therebetween, wherein the channel part includes an insulating film and a nano-compound applied on the insulating film, the insulating film is bonded to the gate and the substrate, and the source and the drain overlap the nano-compound.

To achieve above technical end, according to the present invention, a manufacturing method for a nano-compound field-effect transistor includes: forming a gate on a substrate; forming a channel part by applying a nano-compound on an insulating film; bonding the insulating film of the channel part to the substrate and the gate; and forming a source and a drain to overlap on the nano-compound with the gate disposed therebetween.

### Advantageous Effects

According to the present invention, a nano-compound field-effect transistor may be manufactured conveniently and economically, and therefore, measuring devices using the nano-compound field-effect transistor may be manufactured inexpensively and conveniently.

### BRIEF DESCRIPTION OF THE DRAWINGS

FIG. 1 is an exemplary view illustrating the configuration of a nano-compound field-effect transistor according to the present invention.

FIGS. 2 to 4 are exemplary views illustrating a manufacturing method for a nano-compound field-effect transistor according to the present invention.

FIG. 5 is a planar image for a channel part, a source, and a drain of a nano-compound field-effect transistor according to the present invention.

### EXPLANATION OF REFERENCE NUMERALS

| | |
|---|---|
| 110: substrate | 120: gate |
| 130: channel part | 131: insulating film |
| 132: nano-compound | 140: source |

150: drain

### MODE FOR CARRYING OUT THE INVENTION

Hereinafter, embodiments of the present invention will be described in detail with reference to the accompanying drawings.

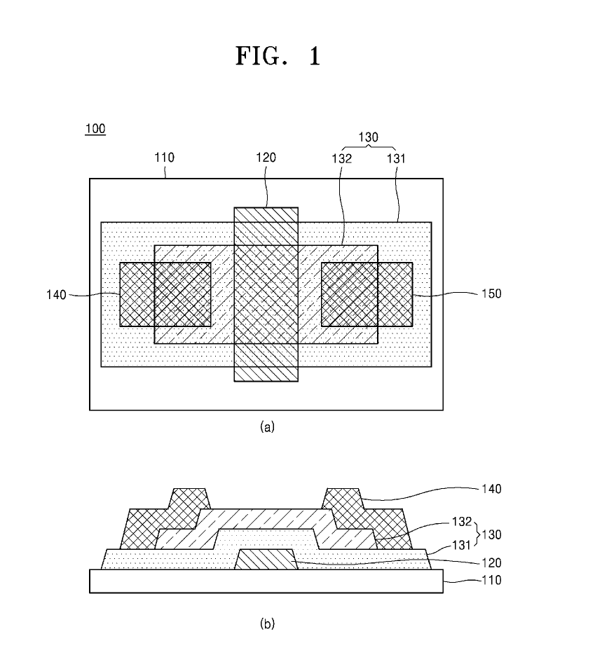

FIG. 1 is an exemplary view illustrating the configuration of a nano-compound field-effect transistor according to the present invention. (a) of FIG. 1 is a plane view of the nano-compound field-effect transistor according to the present invention, and (b) of FIG. 1 is a cross-sectional view of the nano-compound field-effect transistor according to the present invention.

According to the present invention, a nano-compound field-effect transistor 100, as illustrated in (a) and (b) of FIG. 1, includes a gate 120 on a substrate 110, a channel part 130 bonded on the gate so as to overlap with the gate 120, a source 140 at one end of the channel part 130, and a drain facing the source at the other end of the channel part with the gate disposed therebetween.

First, the substrate 110 may be any one among a Si wafer, glass, a PDMS, a PMMA, a PCB, and a flexible film.

Second, the gate 120 may include at least one among various kinds of metals, for example, Ti, Au, Ag, Cu, graphene, Al, Ta, Mg, Nb, Hf, and Zn.

Third, the channel part 130 includes an insulating film 131 and a nano-compound 132 applied on the insulating film 131. The nano-compound may include at least one among, for example, a carbon nanotube (CNT), graphene, or MoS₂.

The insulating film 131 may include any one among polyethylene terephthalate (PET), SiO₂, Al₂O₂, a metal oxide, a metal nitride, a photoresist, a thermosetting resin, an ultraviolet curable resin, a polyimide, and a flexible plastic film.

The nano-compound 132 forms a channel of the nano-compound field-effect transistor according to the present invention.

The nano-compound 132 may be a carbon nanotube.

However, the insulating film 131 may be coated with graphene or MoS₂ together with the carbon nanotube. That is, the nano-compound 132 may include at least one among a carbon nanotube (CNT), graphene, or MoS₂.

Graphite, which is used for pencil leads and is familiar to us, is formed by stacking layers of planes in which carbons are arranged in a honeycombed hexagonal net form. One layer of the graphite is referred to as graphene.

The insulating film 131 is bonded to the gate 120 and the substrate 110.

The insulating film 131 is heated by a laser or microwave, and is bonded to the substrate 110 and the gate 120.

Fourth, the source 140 and the drain 150 are arranged to overlap on the carbon nanotube 132.

The source 140 and the drain 150 are formed by a lithographic or printing process.

The source 140 and the drain 150 may be formed of any one among various kinds of metals, for example, Ti, Au, Ag, Cu, and graphene.

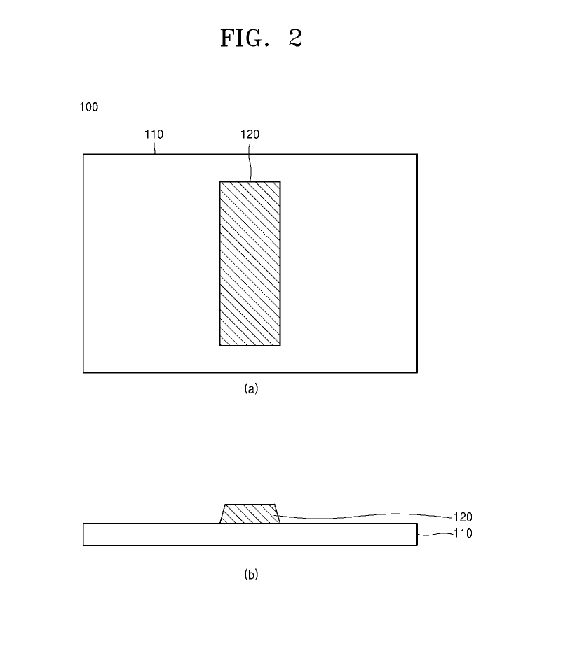

FIGS. 2 to 4 are exemplary views illustrating a manufacturing method for a nano-compound field-effect transistor according to the present invention. (a) in FIGS. 2 to 4 are plan views of the nano-compound field-effect transistor according to the present invention, and (b) in FIGS. 2 to 4 are cross-sectional views of the nano-compound field-effect transistor according to the present invention.

First, as illustrated in (a) and (b) of FIG. 2, a gate 120 is formed on a substrate 110.

The substrate 110 may be any one among a Si wafer, glass, a PDMS, a PMMA, a PCB, and a flexible film.

The gate 120 may be formed to include at least one among various kinds of metals, for example, Ti, Au, Ag, Cu, graphene, Al, Ta, Mg, Nb, Hf, and Zn.

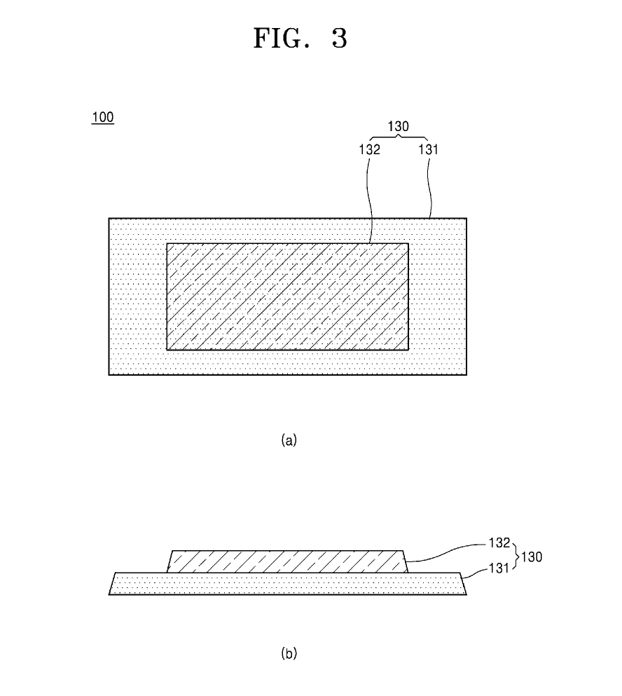

Next, as illustrated in (a) and (b) of FIG. 3, a channel part 130 is formed by applying a nano-compound 132 on an insulating film 131. The nano-compound 132 may be formed to include at least one among, for example, a carbon nanotube (CNT), graphene, or MoS₂.

The insulating film 131 may be formed to include any one among polyethylene terephthalate (PET), SiO₂, Al₂O₂, a metal oxide, a metal nitride, a photoresist, a thermosetting resin, an ultraviolet curable resin, a polyimide, and a flexible plastic film.

When the nano-compound 132 is formed of the carbon nanotube (CNT), PET to which the carbon nanotube (CNT) is easily attached may be used as the insulating film 131.

For example, it is very easy to apply the carbon nanotube (CNT) on the polyethylene terephthalate (PET) due to very strong interaction forces, such as van-der Waals forces. When the channel part 130 applied with the nano-compound 132 is manufactured separately and the channel part 130 is then bonded on the gate 120 using a laser or microwave, a nano-compound field-effect transistor can be manufactured very economically and conveniently. Therefore, according to the present invention, manufacturing costs for the nano-compound field-effect transistor can be saved drastically, and thus, commercialization of measurement devices using the nano-compound field-effect transistor is possible and economic efficiency of the measurement devices can be improved.

The carbon nanotube (CNT) used as the nano-compound 132 may be a single-walled carbon nanotube (SWCNT).

The nano-compound 132 forms a channel of the nano-compound field-effect transistor according to the present invention. One layer of graphite is referred to as graphene.

The carbon nanotube, or the graphene together with the carbon nanotube 132, may be applied on the insulating film 131.

Furthermore, the insulating film 131 may be applied with at least one of graphene or MoS₂ together with the carbon nanotube.

That is, the channel part 130 may be formed by applying, on the insulating film 131, at least one among the carbon nanotube 132, graphene, or MoS₂.

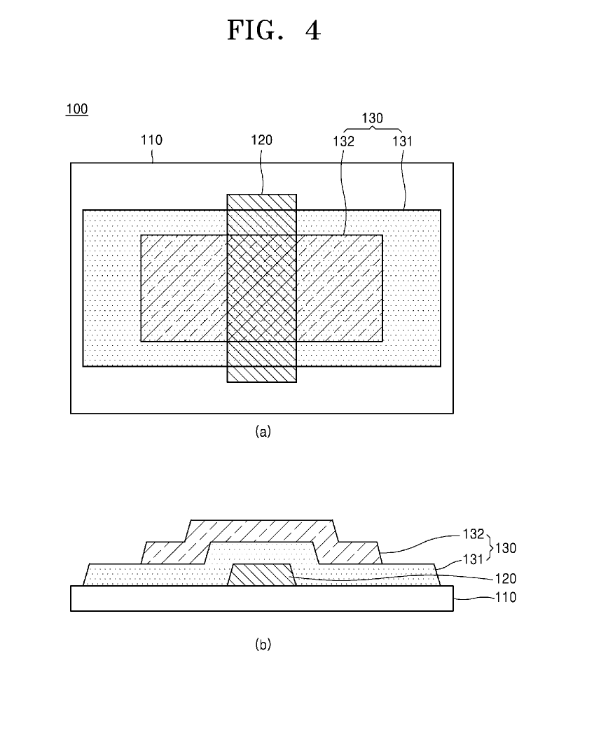

Next, as illustrated in (a) and (b) of FIG. 4, the insulating film 131 of the channel part 130 is bonded on the substrate 110 and the gate 120.

The insulating film 131 is heated by a laser or microwave, and is bonded on the gate 120 and the substrate 110.

As the insulating film 131 is bonded on the gate 120 and the substrate 110, the nano-compound 132 formed on the insulating film 131 may also be disposed over the substrate 110 and the gate 120.

Finally, as illustrated in (a) and (b) of FIG. 1, a source 140 and a drain 150 are formed to overlap the nano-compound 132 with the gate 120 disposed therebetween.

The source 140 and the drain 150 are formed by a lithographic or printing process.

The source 140 and the drain 150 may be formed of any one among various kinds of metals, for example, Ti, Au, Ag, Cu, and graphene.

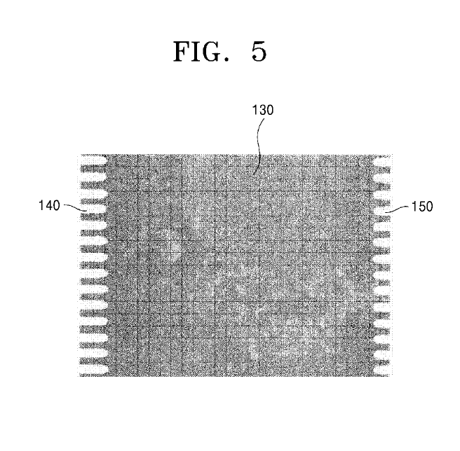

FIG. 5 is a planar image for a channel part, a source, and a drain of a nano-compound field-effect transistor according to the present invention.

In the nano-compound field-effect transistor according to the present invention, as illustrated in the description above and FIG. 5, the channel part 131 is formed by partially applying a nano-compound on the insulating film 131, and the source 140 and the drain 150 are formed at both ends of the channel part 130 by a photolithographic process.

Hereinafter, the present invention described above is briefly summarized.

The present invention relates to a large-area nano-compound field-effect transistor, and more particularly, to a nano-compound field-effect transistor applicable to a semiconductor chip for gas detection or biomarker measurement.

According to the present invention, since a channel can be stably formed by a nano-compound including at least one among a carbon nanotube, graphene, or MoS₂, the semiconductor chip using the stable nano-compound field-effect transistor can be manufactured, thereby drastically improve biomarker detection technology.

According to the present invention, the semiconductor chip having the economical and stable nano-compound field-effect transistor can be manufactured, and therefore, real-time early diagnosis of disease, infectious disease, cancer, and the like using an antibody, etc. is possible. Accordingly, spread of infectious disease can be blocked fundamentally, and a measurement device by which the health is protected from disease and cancer can be manufactured.

In addition, although the conventional measurement device for performing the above described functions uses an optical or fluorescent type one, the conventional measurement device is disadvantageous in a long measurement time and accuracy as well.

When the biosensor using the semiconductor chip, to which the nano-compound field-effect transistor according to the present invention is applied, is used, various diseases can be measured in real-time after taking a small amount of blood or body fluid immediately on the spot. Therefore, according to the present invention, disease and infectious disease can be early detected, and thus, national insurance costs for identifying infected persons can be reduced.

According to the present invention as described above, since stability and economic efficiency of manufacturing the semiconductor chip using the nano-compound field-effect transistor can be achieved, a disposable biomarker measurement device, which measures multiple diseases or infectious disease in real-time using a small amount of body fluid, can be manufactured.

It will be understood by those skilled in the art to which the present invention pertains that the present invention may be embodied in other specific forms without changing the technical spirit or essential features of the present invention. Therefore, it is to be understood that the embodiments described above are illustrative in all aspects and not restrictive. The scope of the present invention is defined by the appended claims rather than the above detailed description, and it should be understood that all modifications or variations derived from the meanings and scope of the claims and equivalents thereof are included in the scope of the present invention.

1. A nano-compound field-effect transistor, comprising:
a gate on a substrate;
a channel part bonded on the gate so as to overlap with the gate;
a source at one end of the channel part; and
a drain facing the source at the other end of the channel part with the gate disposed therebetween,
wherein the channel part comprises an insulating film and a nano-compound applied on the insulating film,
wherein the insulating film is bonded to the gate and the substrate, and
wherein the source and the drain overlap the nano-compound.

2. The nano-compound field-effect transistor of claim 1, wherein the insulating film is selected from the group consisting of: polyethylene terephthalate (PET), SiO₂, Al₂O₂, a metal oxide, a metal nitride, a photoresist, a thermosetting resin, an ultraviolet curable resin, a polyimide, and a flexible plastic film.

3. The nano-compound field-effect transistor of claim 1, wherein the nano-compound comprises at least one of a carbon nanotube (CNT), graphene, or MoS₂.

4. A manufacturing method for a nano-compound field-effect transistor, the method comprising:
forming a gate on a substrate;
forming a channel part by applying a nano-compound on an insulating film;
bonding the insulating film of the channel part to the substrate and the gate; and forming a source and a drain to overlap on the nano-compound with the gate disposed therebetween.

5. The method of claim 4, wherein the insulating film is heated by a laser or microwave and bonded to the gate and the substrate.

6. The method of claim 4, wherein the insulating film is selected from the group consisting of: PET, SiO₂, Al₂O₂, a metal oxide, a metal nitride, a photoresist, a thermosetting resin, an ultraviolet curable resin, a polyimide, and a flexible plastic film.

7. The method of claim 4, wherein the forming of the nano-compound comprises at least one of a carbon nanotube (CNT), graphene, or MoS₂.
